(19) United States
(12) Patent Application Publication
(10) Pub. No.: US 2017/0243990 A1
(43) Pub. Date: Aug. 24, 2017

(54) SOLAR PANEL USING LIGHT GUIDING COMPONENT

(71) Applicant: Eterbright Solar Corporation, Miaoli County (TW)

(72) Inventor: Nan Chi Lin, Miaoli County (TW)

(73) Assignee: Eterbright Solar Corporation, Miaoli County (TW)

(21) Appl. No.: 15/086,385

(22) Filed: Mar. 31, 2016

(30) Foreign Application Priority Data
Feb. 18, 2016 (TW) 105202310

(51) Int. Cl. H01L 31/0236; H01L 31/048; H01L 31/054

(52) U.S. Cl. CPC H01L 31/02366; H01L 31/054; H01L 31/048

(57) ABSTRACT

A solar panel using a light guiding component for receiving external light includes at least one solar cell, a transparent back plate, a transparent cover plate, a light guiding component and a packaging material. The transparent back plate is located on a first side of the solar cell. The transparent cover plate is located on a second side of the solar cell for passing and projecting the light to the solar cell and the transparent back plate. The light guiding component is located on the first side of the solar cell. The packaging material is disposed between the transparent cover plate and the transparent back plate for packaging the solar cell. The solar cell is packaged between the transparent back plate and the transparent cover plate, such that after the light projects to the light guiding component, the light guiding component scatters the light.

### CROSS REFERENCE TO RELATED APPLICATIONS

This non-provisional application claims priority under 35 U.S.C. §119(a) on Patent Application No. 105202310 filed in Taiwan, R.O.C. on Feb. 18, 2016, the entire contents of which are hereby incorporated by reference.

### BACKGROUND OF THE INVENTION

### Field of the Invention

The present invention relates to a solar panel, and more particularly to the solar panel capable of guiding and scattering light by using a light guiding component.

### Description of Related Art

To cope with the requirements of energy saving and carbon reduction, solar panels are installed to the glass of some apartments or office buildings. However, these solar panels come with at least one opaque power generation area, so that the light received by the solar panels cannot penetrate. In other words, if the solar panels are installed to the glass of the apartments or office buildings, some of the external light received by the solar panels would be blocked by the power generation area and cannot penetrate through the solar panels. As a result, the indoor light is weak and the brightness is non-uniform.

Therefore, it is an important subject for related manufacturers or designers to overcome the aforementioned problem.

### SUMMARY OF THE INVENTION

It is a primary objective of the present invention to provide a solar panel using a light guiding component capable of guiding and scattering light.

To achieve the aforementioned and other objectives, the present invention provides a solar panel using a light guiding component and configured to receive external light, wherein the solar panel comprises at least one solar cell, a transparent back plate, a transparent cover plate, a light guiding component and a packaging material. The transparent back plate is located on a first side of the solar cell. The transparent cover plate is located on a second side of the solar cell, and the light can pass through the transparent cover plate and projects to the solar cell and the transparent back plate. The light guiding component is located on the first side of the solar cell. The packaging material is located between the transparent cover plate and the transparent back plate and configured to package the solar cell. The solar cell is packaged between the transparent back plate and the transparent cover plate, such that after a light projects into the light guiding component, the light guiding component would scatter the light.

In the aforementioned solar panel, light guiding component is a light guiding plate.

In the aforementioned solar panel, the light guiding plate includes a bright area and a dark area, and the dark area corresponds to the solar cell, and the bright area doesn't correspond to the solar cell, and the light guiding plate thickens gradually from the dark area to the bright area.

In the aforementioned solar panel, the light guiding plate is made of silicone, acrylic, or glass.

In the aforementioned solar panel, the light guiding component is a light guiding pattern.

In the aforementioned solar panel, the light guiding pattern is formed on an upper surface or a lower surface of the transparent back plate by embossing.

In the aforementioned solar panel, the light guiding pattern is formed on the transparent back plate by screen printing.

In the aforementioned solar panel, the solar panel further comprises a waterproof plastic material located between the transparent cover plate and the transparent back plate and around outer sides of the solar panel.

In the aforementioned solar panel, the light guiding component has a serrated structure.

In the aforementioned solar panel, the light guiding component includes a bright area and a dark area, and the dark area corresponds to the solar cell, and the bright area doesn't correspond to the solar cell, and the teeth of the serrated structure are larger in bright area than in dark area. Moreover, the teeth of the serrated structure become bigger gradually from the dark area to the bright area.

The technical characteristics, contents, advantages and effects of the present invention will be apparent with the detailed description of a preferred embodiment accompanied with the illustration of related drawings as follows.

### BRIEF DESCRIPTION OF THE DRAWINGS

FIG. 1A is a cross-sectional view of a solar panel using a light guiding component of the present invention;

FIG. 1B is a top view of a solar panel using a light guiding component of the present invention;

FIG. 1C is a schematic view of one of the implementation modes of a light guiding plate of the present invention;

FIG. 1D is a schematic view of a surface of a light guiding plate of the present invention;

FIG. 2A is a cross-sectional view of a solar panel using a light guiding component in accordance with another embodiment of the present invention;

FIG. 2B is a top view of a solar panel using a light guiding component in accordance with another embodiment of the present invention;

FIG. 3A is a cross-sectional view of a solar panel using a light guiding component in accordance with a further embodiment of the present invention;

FIG. 3B is a schematic view of a light guiding pattern of the present invention; and

FIG. 4 is a cross-sectional view of a printed layer of the present invention.

### DETAILED DESCRIPTION OF THE INVENTION

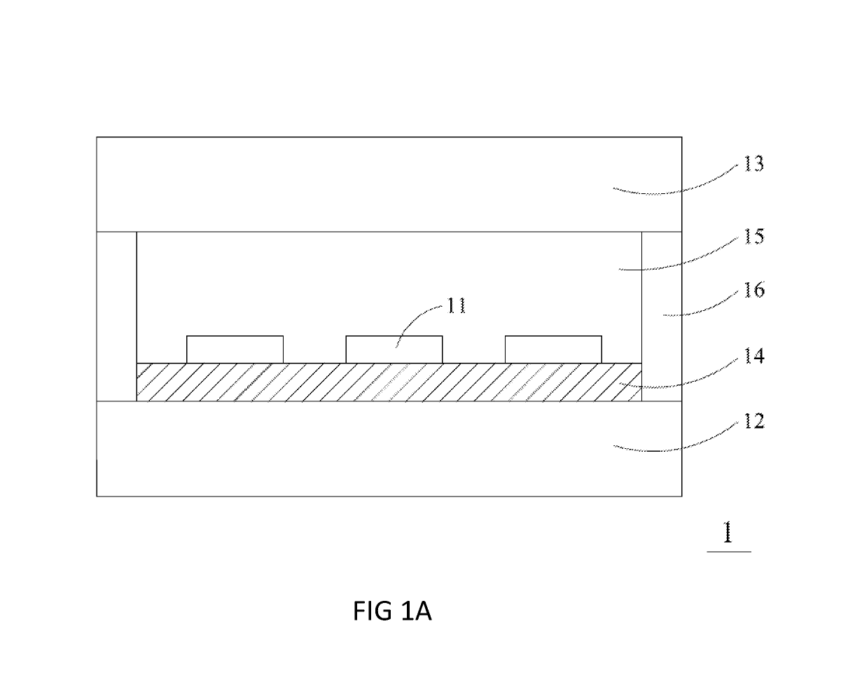

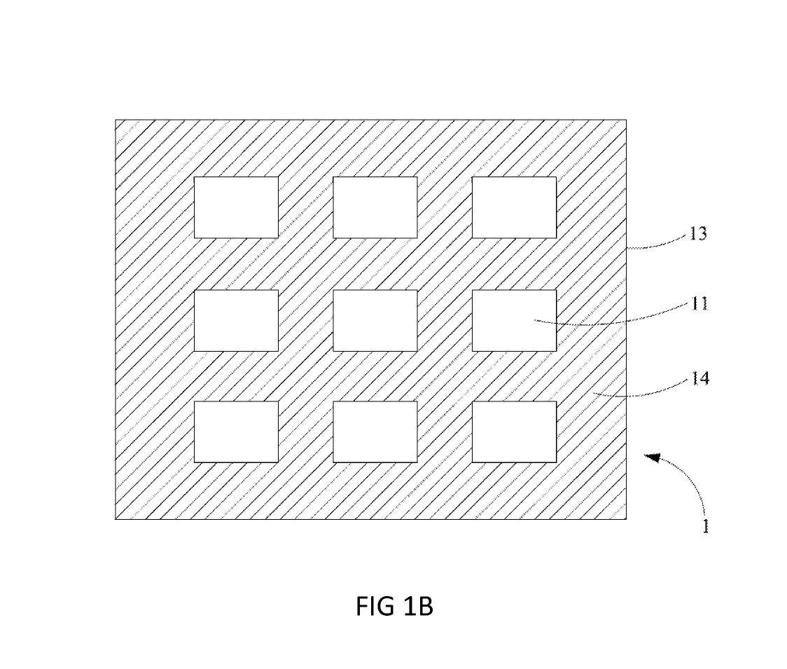

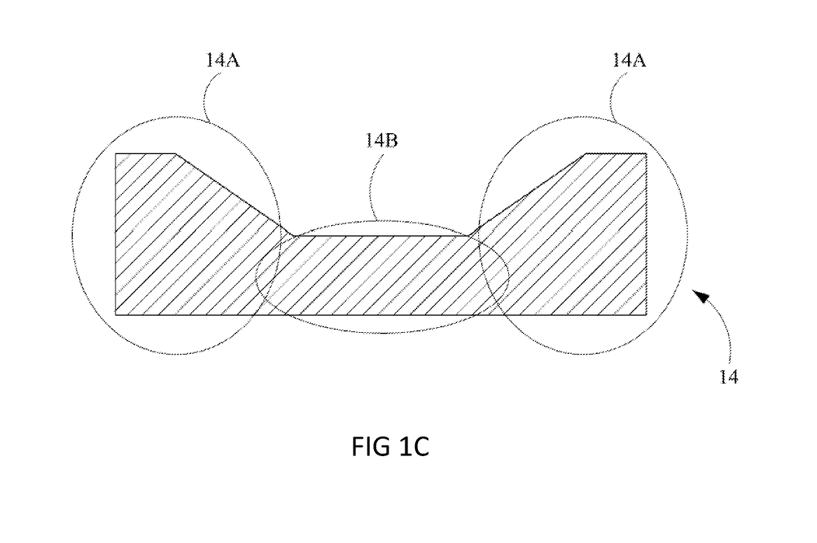

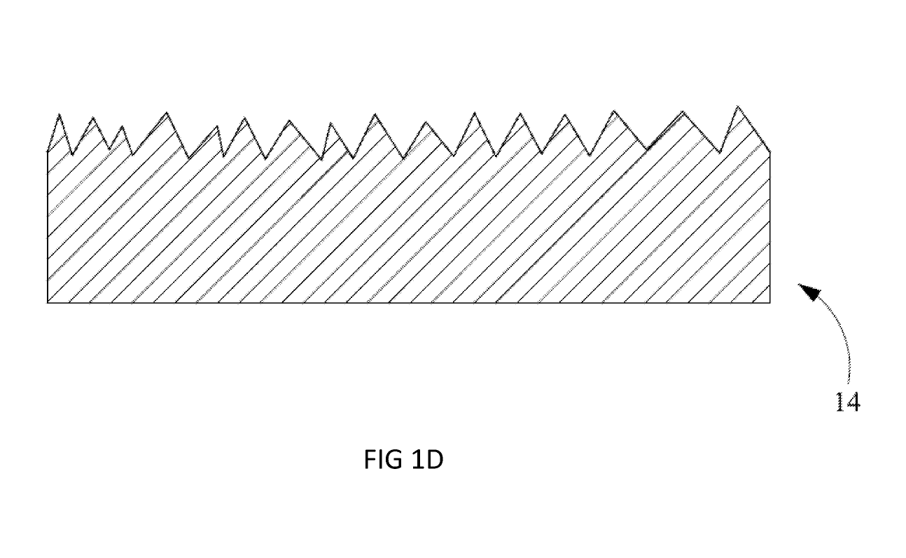

With reference to FIGS. 1A and 1B for the cross-sectional view and top view of a solar panel using a light guiding component of the present invention respectively, the present invention provides a solar panel 1 capable of scattering and guiding light, and the solar panel 1 is provided for receiving external light, and the solar panel 1 comes with a structure of two layers of glass and a film included between the two layers of glass. The solar panel 1 comprises at least one solar cell 11, a transparent back plate 12, a transparent cover plate 13, a light guiding plate 14, a packaging material 15, and a waterproof plastic material 16. The transparent back plate 12 is located on a first side of the solar cell 11 (which is the bottom side of the solar cell 11 as shown in the figures). The transparent cover plate 13 is located on a second side of the solar cell 11 (which is the top side of the solar cell 11 as shown in the figures) and provided for passing the light through the transparent cover plate 13 and projecting the light to the solar cell 11 and the transparent back plate 12. For example, the transparent back plate 12 and the transparent cover plate 13 both have a structure made of glass.

The light guiding plate 14 is located on the first side of the solar cell 11 for guiding and scattering the light entering into the transparent cover plate 13. The light guiding plate 14 may be a uniform thin plate or any plate with another shape and capable of improving the light guiding effect. With reference to FIG. 1C for one of the implementation modes of a light guiding plate of the present invention, FIG. 1C bases on the light guiding portion corresponding to a single solar cell 1 as depicted in FIG. 1A to illustrate the invention, and the light guiding portion of the light guiding plate 14 includes at least one bright area 14A not corresponding to the solar cell 11 and at least one dark area 14B corresponding to the solar cell 11. The dark area 14B is covered by the solar cell 1 (when observing from the top view of the transparent cover plate 13). The bright area 14A is not covered by the solar cell 1 (when observing from the top view of the transparent cover plate 13). The light guiding plate 14 thickens gradually from the dark area 14B to the bright area 14A. Specifically, the portion of the light guiding plate 14 not covered by the solar cell 11 is designed to be thicker, so that more of the external light has the scattering effect. With reference to FIG. 1D for a schematic view of a surface of a light guiding plate, the whole or a portion of the light guiding plate 14 may not be a smooth plane (such as a serrated structure) and the light guiding plate 14 is made of a material such as silicone, acrylic, or glass. It is noteworthy that the size and depth of the serrated structure in the bright area 14A and the dark area 14B may be different. For example, the teeth of the serrated shape of the bright area 14A become smaller in a direction towards the dark area 14B.

The packaging material 15 is located between the transparent cover plate 13 and the transparent back plate 12 for packaging the solar cell 11. The waterproof plastic material 16 is located between the transparent cover plate 13 and transparent back plate 12 and around the outer sides of the solar panel 1, and the waterproof plastic material 16 is provided for wrapping the packaging material 15 securely. In other words, the solar cell 11 is wrapped by the packaging material 15 and the waterproof plastic material 16 securely, so that the solar cell 11 would not be affected by moisture or mechanical forces. Therefore, the solar cell 11 of the solar panel 1 would not be deteriorated by moisture, and the normal effective operation of the solar panel 1 can be maintained. The packaging material 15 includes but not limited to ethylene vinyl acetate (EVA), polyolefin (PO), polyvinyl butyral (PVB), or UV curable encapsulant, and the waterproof plastic material 16 includes but not limited to thermoplastic polyolefin (TPO) or butyl rubber.

The solar cell 11 is packaged between the transparent back plate 12 and the transparent cover plate 13, and the solar cell 11 has an opaque photoelectric conversion component for performing a photoelectric conversion of the received light, so that the solar panel 1 generates and supplies power. The solar cell 11 may be a conventional monosilicon or polysilicon cell or a thin-film solar cell, such as a solar cell including copper (Cu), indium (In), gallium (Ga) and selenium (Se), or including Group Ib elements such as copper (Cu) or silver (Ag), Group IIIb elements such as aluminum (Al), gallium (Ga) or indium (In) and Group VIb elements such as sulfur (S), selenium (Se) or tellurium (Te). In this preferred embodiment, the solar cell 11 is a copper indium gallium diselenide (CIGS) thin-film cell with the features of large light absorbing area, wide light absorbing range (Infrared region from 700 nm to 1,200 nm) and high photoelectric conversion efficiency (up to 19.9%), but the solar cell 11 may also be a monosilicon cell capable of achieving the photoelectric conversion effect.

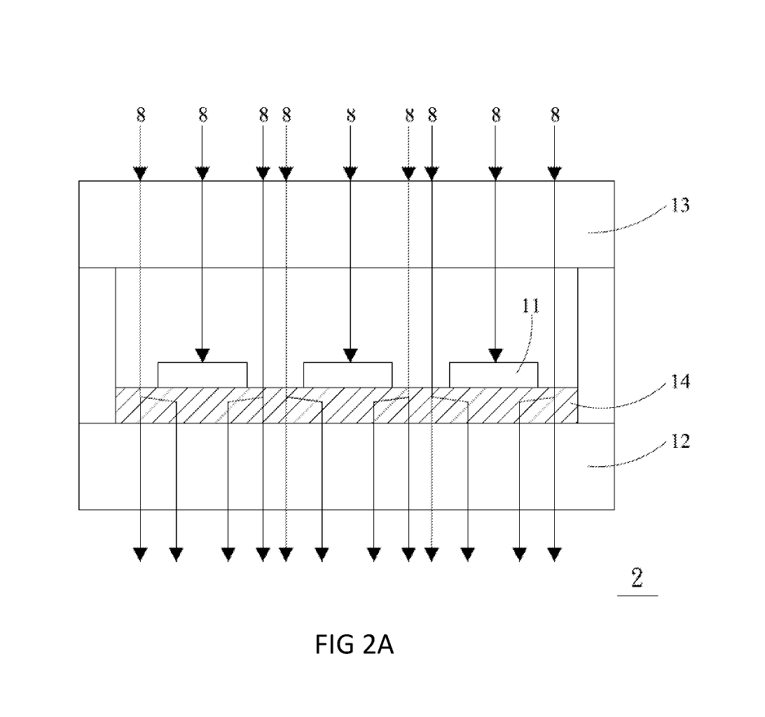

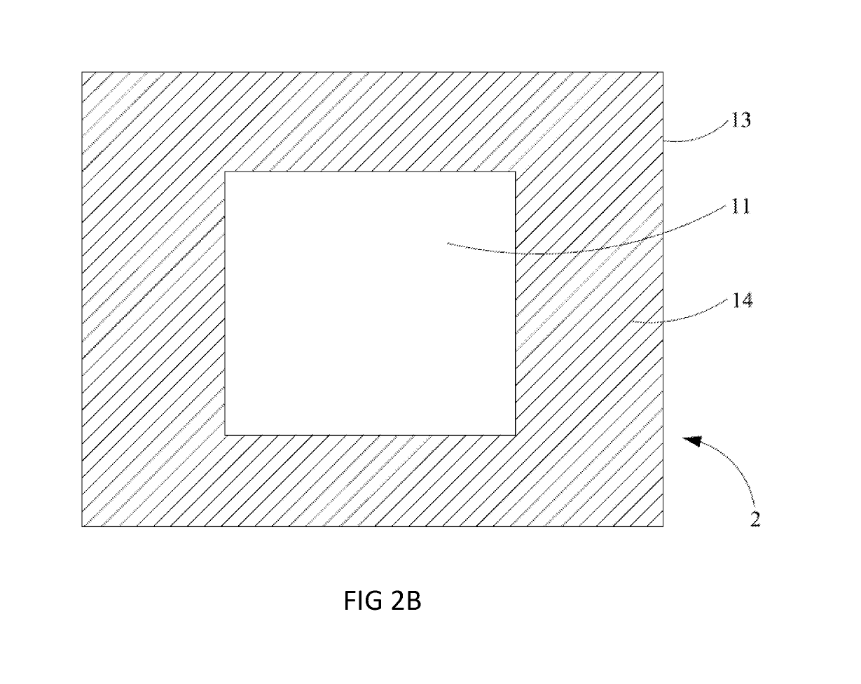

With reference to FIGS. 2A and 2B for the cross-sectional view and top view of a solar panel using a light guiding component in accordance with in accordance with another preferred embodiment of the present invention respectively, the solar panel 2 of this embodiment includes all technical characteristics of the solar panel 1 of the previous embodiment and further includes the technical characteristic of guiding the light 8 in the portion of the solar panel 1 including a single solar cell 11. When an external light 8 penetrates through the transparent cover plate 13 into the solar panel 2, a part of the light 8 would be blocked by the photoelectric conversion area of the solar cell 11 and cannot pass through the solar panel 2 while the remaining part of the light 8 (situated on both sides as shown in FIG. 2A) is scattered by the light guiding plate 14 and preferably scattered to every part of the light exit surface of the light guide plate 14 uniformly. Since the light guiding plate 14 thickens gradually from the dark area 14B to the bright area 14A, so that the light 8 can be scattered uniformly from the bright area 14A to the dark area 14B more easily, and the light 8 is guided out from the transparent back plate 12 of the solar panel 2. Therefore, if the solar panel 2 is installed to the glass around apartments or office buildings, then the light 8 will be guided out from the solar panel 2 uniformly to improve the uniformity of the indoor light significantly and prevent non-uniform brightness. Persons having ordinary skill in the art should understand that FIGS. 2A and 2B are provided for illustrating that the light 8 in the light guiding plate 14 is scattered, but do not represent the actual light path of the light 8 in the light guiding plate 14.

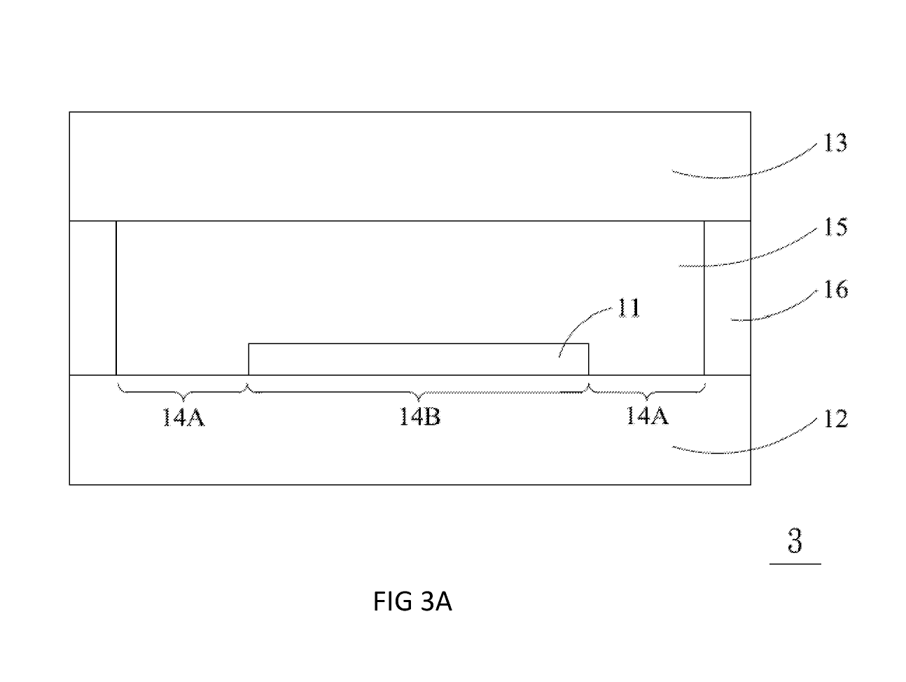

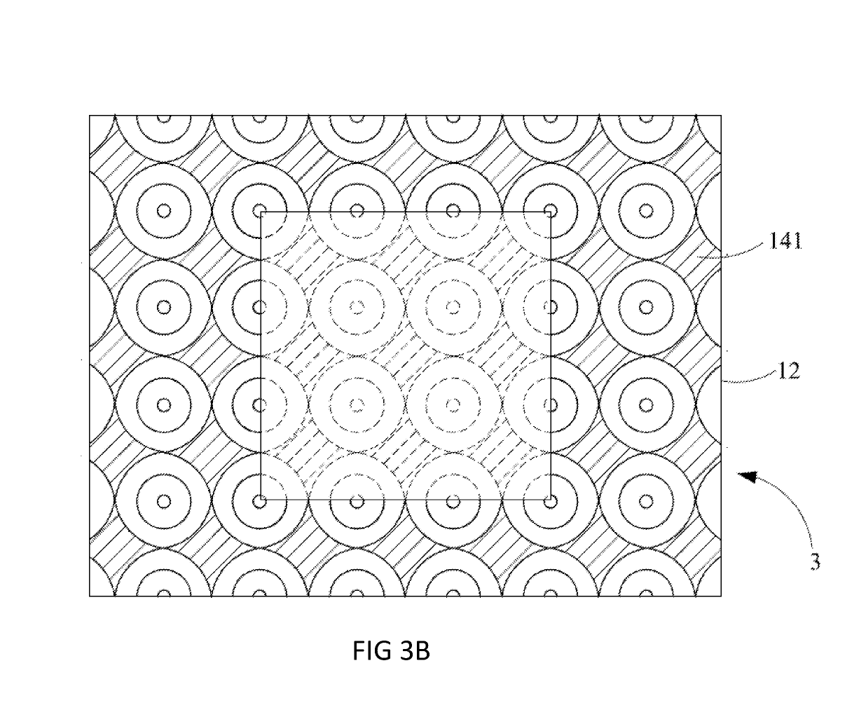

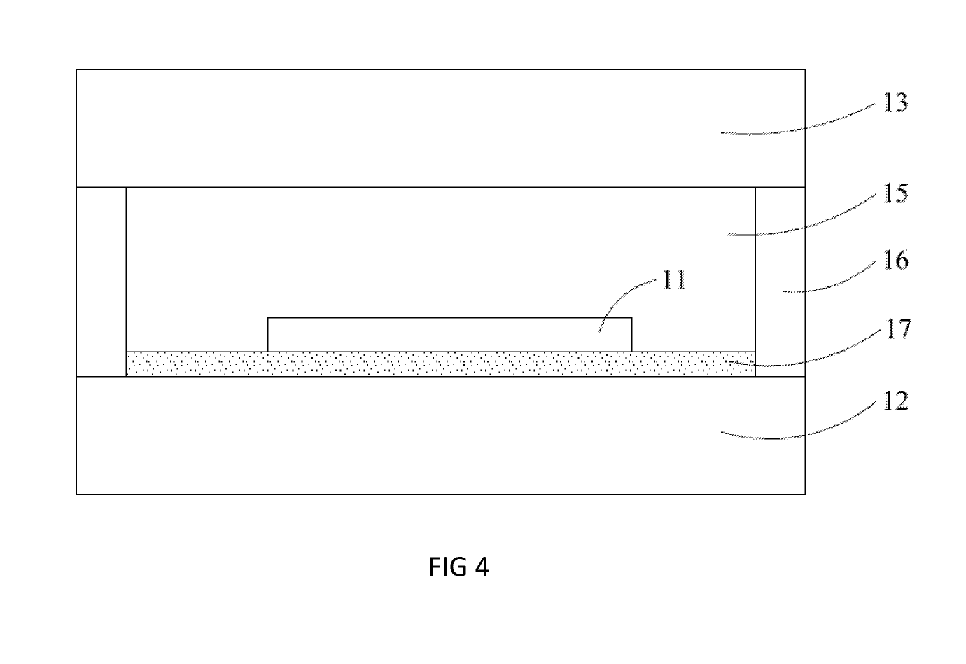

The light guiding component includes a bright area 14A and a dark area 14B, and the dark area 14B corresponds to the solar cell 11, and the bright area 14A doesn't correspond to the solar cell 11. The light guiding component has a serrated structure, and the teeth of the serrated structure are larger in bright area than in dark area. Moreover, the teeth of the serrated structure become smaller gradually from the bright area 14A to the dark area 14B. In another preferred embodiment, the light guiding component may be a light guiding pattern pressed and manufactured on the surface of the transparent back plate 12 directly (such as the light guiding pattern 141 as shown in FIG. 3B). With FIGS. 3A and 3B for the cross-sectional view of a solar panel using a light guiding component and the schematic view of a light guiding pattern in accordance with a further preferred embodiment of the present invention respectively, the light guiding pattern 141 is formed on an upper surface or a lower surface of the transparent back plate 12 directly by embossing. In this preferred embodiment, the transparent back plate 12 is also divided into a bright area 14A and a dark area 14B, and the dark area 14B corresponds to the solar cell 11 and is covered by the solar cell 11 (when observing from the top view of the transparent cover plate 13). The bright area 14A doesn't correspond to the solar cell 11 and is not covered by the solar cell 11 (when observing from the top view of the transparent cover plate 13). The light guiding pattern 141 is formed at the portion of the bright area 14A of the upper surface of the transparent back plate 12, wherein the light guiding pattern 141 may be a serrated rhombus, square, circle or any other serrated shape. In a preferred embodiment, the light guiding pattern 141 is formed at the bright area 14A and the dark area 14B of the whole transparent back plate 12 and is more complicated than the light guiding pattern 141 at the dark area 14B or the light guiding pattern 141 at the bright area 14A, so that the light energy entering into the portion of the bright area 14A can be scattered uniformly to the portion of the dark area 14B. With reference to FIG. 4 for the cross-sectional view of a printed layer of the present invention, the light guiding pattern 141 is formed on the transparent back plate 12 by screen printing. Specifically, a printed layer 17 is formed on the transparent back plate 12 by screen printing, so that the light guiding pattern 141 can be printed onto the transparent back plate 12 through the printed layer 17, and the light guiding pattern 141 of the light guiding plate 14 formed by screen printing as shown in FIG. 3B is capable of achieving the same effect of scattering the entered light.

Compared with the conventional solar panel, the solar panel 1 using a light guiding plate in accordance with the present invention is capable of guiding and scattering light uniformly. Specifically, the solar panel 2 includes a light guiding plate 14 or a light guiding pattern 141 for scattering the received external light and guiding the light out from the solar panel 1.

While the invention has been described by means of specific embodiments, numerous modifications and variations could be made thereto by those skilled in the art without departing from the scope and spirit of the invention set forth in the claims.

What is claimed is:

1. A solar panel for receiving an external light, comprising:
at least one solar cell;
a transparent back plate, located on a first side of the solar cell;
a transparent cover plate, located on a second side of the solar cell, for passing the external light through the transparent cover plate and projecting the external light to the at least one solar cell and the transparent back plate;
a light guiding component, located on the first side of the solar cell; and
a packaging material, located between the transparent cover plate and the transparent back plate, for packaging the solar cell;
wherein, the solar cell is packaged between the transparent back plate and the transparent cover plate, such that after the external light projects to the light guiding component, the light guiding component scatters the external light.

2. The solar panel according to claim 1, wherein the light guiding component is a light guiding plate.

3. The solar panel according to claim 2, wherein the light guiding plate includes a bright area and a dark area, and the dark area corresponds to the solar cell, and the bright area doesn't correspond to the solar cell, and the light guiding plate thickens gradually from the dark area to the bright area.

4. The solar panel according to claim 2, wherein the light guiding plate is made of silicone, acrylic, or glass.

5. The solar panel according to claim 1, wherein the light guiding component is a light guiding pattern.

6. The solar panel according to claim 5, wherein the light guiding pattern is a embossed pattern on an upper surface or a lower surface of the transparent back plate.

7. The solar panel according to claim 5, wherein the light guiding pattern is a printed pattern on the transparent back plate.

8. The solar panel according to claim 1, further comprising a waterproof plastic material located between the transparent cover plate and the transparent back plate and around outer sides of the solar panel.

9. The solar panel according to claim 1, wherein the light guiding component has a serrated structure.

10. The solar panel according to claim 9, wherein the light guiding component includes a bright area and a dark area, and the dark area corresponds to the solar cell, and the bright area doesn't correspond to the solar cell, and teeth of the serrated structure are larger in bright area than in dark area.
